(19) United States
(12) Patent Application Publication
(10) Pub. No.: US 2018/0295752 A1
(43) Pub. Date: Oct. 11, 2018

(54) COOLING SYSTEM EMPLOYABLE IN DATA CENTER

(71) Applicant: Beijing Baidu Netcom Science and Technology Co., Ltd., Beijing (CN)

(72) Inventors: Hu Tang, Beijing (CN); Binghua Zhang, Beijing (CN); Tianyu Zhou, Beijing (CN)

(21) Appl. No.: 15/889,914

(22) Filed: Feb. 6, 2018

(30) Foreign Application Priority Data
Apr. 6, 2017 (CN) 201710221909.3

(51) Int. Cl. H05K 7/20; F25B 5/02

(52) U.S. Cl. CPC H05K 7/20827; F25B 5/02; H05K 7/20836; H05K 7/20381; H05K 7/20318; H05K 7/20327; H05K 7/20354; H05K 7/20309

(57) ABSTRACT

The present disclosure discloses a cooling system employable in data centers. An specific embodiment of the cooling system comprises: a first refrigeration medium, a first evaporator, a first condenser, and an all-condition cooling tower, wherein: the first evaporator is installed in a to-be-cooled space, the first evaporator is connected to the first condenser, an installation position of the first condenser is higher than an installation position of the first evaporator; the first condenser is connected to the all-condition cooling tower, and the all-condition cooling tower is disposed outside the to-be-cooled space, the all-condition cooling tower is used for providing the first condenser with a cold source for cooling the first refrigeration medium in a gaseous state. The cooling system provided by the embodiment has the advantages of simple structure, convenient installation and maintenance and low cost.

### CROSS-REFERENCE TO RELATED APPLICATION

This application claims the priority of Chinese Patent Application No. 201710221909.3, entitled “Cooling System Applied to Data Center,” filed on Apr. 6, 2017, the content of which is incorporated herein by reference in its entirety.

### TECHNICAL FIELD

This application relates to the field of mechanical engineering, particularly to the cooling technology, and more particularly to a cooling system employable in data centers.

### BACKGROUND

With the deepening of the information revolution and the development of the mobile Internet era in particular, more and more data have been generated in the digital era. Naturally, more and more data centers are required to be built to carry and operate on these data. Electronic equipment in the data centers needs to dissipate heat during operation, therefore, the data center generally needs to set up a cooling system.

However, the existing cooling systems employed in data centers are generally complex in structure, which leads to the problems of inconvenient installation and maintenance and higher costs.

### SUMMARY

The purpose of present disclosure is to propose an improved cooling system employable in data centers to solve the technical problems mentioned in the above background section.

The present disclosure provides a cooling system employable in data centers, the cooling system comprises a first refrigeration medium, a first evaporator, a first condenser and an all-condition cooling tower, wherein: the above-mentioned first evaporator is installed in a to-be-cooled space, the above-mentioned first evaporator is connected to the above-mentioned first condenser, an installation position of the above-mentioned first condenser is higher than an installation position of the above-mentioned first evaporator, the above-mentioned first refrigeration medium in the above-mentioned first evaporator absorbs heat from the above-mentioned to-be-cooled space and is vaporized into the first refrigeration medium in a gaseous state, the above-mentioned first refrigeration medium in the gaseous state rises to the above-mentioned first condenser and is cooled by the above-mentioned first condenser to be liquefied into the first refrigeration medium in a liquid state, the above-mentioned first refrigeration medium in the liquid state returns to the above-mentioned first evaporator; and the above-mentioned first condenser is connected to the all-condition cooling tower, the above-mentioned all-condition cooling tower is disposed outside the above-mentioned to-be-cooled space, and the above-mentioned all-condition cooling tower is used for providing the above-mentioned first condenser with a cold source cooling the above-mentioned first refrigeration medium in the gaseous state.

In some embodiments, the above-mentioned first condenser comprises a main first condenser and a standby first condenser, the above-mentioned main first condenser and the above-mentioned standby first condenser are both connected to the above-mentioned first evaporator, and the above-mentioned main first condenser or the above-mentioned standby first condenser cools the above-mentioned gaseous first refrigeration medium.

In some embodiments, the above-mentioned first evaporator and the above-mentioned first condenser are connected through a flexible hose, and the above-mentioned flexible hose is provided with a quick coupling.

In some embodiments, the above-mentioned cooling system further comprises a control apparatus, and a temperature sensor, a barometric sensor and a valve in communication with the above-mentioned control apparatus, wherein: the above-mentioned temperature sensor and the above-mentioned barometric sensor are both disposed in the to-be-cooled space; the above-mentioned valve is disposed at a connecting pipe transporting the cold source from the above-mentioned all-condition cooling tower to the above-mentioned first condenser; the above-mentioned control apparatus is used for defining an opening of the above-mentioned valve according to a temperature value and a pressure value respectively collected by the above-mentioned temperature sensor and the above-mentioned barometric sensor.

In some embodiments, the above-mentioned first refrigeration medium is an organic refrigeration medium.

In some embodiments, a to-be-cooled device is provided by the above-mentioned to-be-cooled space, the above-mentioned first evaporator is an aluminum micro-channel heat exchanger, and the above-mentioned micro-channel heat exchanger is installed on the above-mentioned to-be-cooled device as a backplane.

In some embodiments, the above-mentioned cooling system further comprises a water pump installed on a connecting pipe between the above-mentioned all-condition cooling tower and the above-mentioned first condenser.

In some embodiments, the above-mentioned all-condition cooling tower comprises a second refrigeration medium, a second condenser, a second compressor, and a closed cooling tower comprising a heat radiating coil and a second evaporator, wherein: the above-mentioned heat radiating coil is connected to the above-mentioned first condenser, the above-mentioned second refrigeration medium absorbs heat of the above-mentioned first refrigeration medium in the above-mentioned first condenser, and the above-mentioned second refrigeration medium after absorbing heat cools in the above-mentioned heat radiating coil, the above-mentioned cooled second refrigeration medium returns to the above-mentioned first condenser; and the above-mentioned second compressor is connected to the above-mentioned second evaporator and the above-mentioned second condenser, the above-mentioned second compressor and the above-mentioned second condenser provide the cold source for the second refrigeration medium in the above-mentioned heat radiating coil through the above-mentioned second evaporator.

In some embodiments, the above-mentioned second refrigeration medium is a non-aqueous refrigeration medium, and an installation position of the above-mentioned heat radiating coil is higher than the installation position of the above-mentioned first condenser, the above-mentioned second refrigeration medium absorbs heat of the above-mentioned first refrigeration medium, and is vaporized into the second refrigeration medium in a gaseous state, the above-mentioned second refrigeration medium in the gaseous state rises to the above-mentioned heat radiating coil, and the above-mentioned second refrigeration medium in the gaseous state releases heat in the above-mentioned heat radiating coil and is liquefied into the second refrigeration medium in a liquid state, the above-mentioned second refrigeration medium in the liquid state returns to the above-mentioned first condenser.

In some embodiments, the above-mentioned all condition cooling tower comprises a third refrigeration medium, a third compressor, a third condenser, a third evaporator, and an open cooling tower comprising a spraying component and a water collector locating below the above-mentioned spraying component, wherein: the above-mentioned spraying component is connected to a water outlet of the above-mentioned first condenser, the above-mentioned spraying component is used for spraying the third refrigeration medium received from the water outlet of the above-mentioned first condenser, wherein the sprayed third refrigeration medium exchanges heat with the air for releasing heat, and the third refrigeration medium falls into the above-mentioned water collector after releasing the heat; the above-mentioned third evaporator is disposed in the above-mentioned water collector, and the above-mentioned third evaporator is used for cooling the third refrigeration medium after releasing the heat; the above-mentioned water collector is connected to a water inlet of the above-mentioned first condenser, the above-mentioned water collector is used for: receiving an third refrigeration medium after releasing the heat, and transporting the third refrigeration medium cooled through the above-mentioned third evaporator to the above-mentioned first condenser; and the above-mentioned third compressor is connected to the above-mentioned third condenser and the above-mentioned third evaporator, the above-mentioned third condenser and the above-mentioned third compressor are used for providing the above-mentioned third evaporator with the cold source.

The cooling system employable in the data center provided by the embodiments of the present disclosure utilizes the phase change of the first refrigeration medium for heat exchange, which improves the cooling efficiency. The cooling water of higher temperature provided by the all-condition cooling towers for the above-mentioned first condenser meets the cooling needs of the data center, which eliminates the installation of the cooling units in the existing technology. The cooling system provided by the present embodiment has advantages of a simple structure, convenient installation and maintenance, and low cost.

### BRIEF DESCRIPTION OF THE DRAWINGS

Other features, objects, and advantages of the present disclosure will become more apparent by reading the detailed description of the non-limiting embodiments with reference to the following drawings:

FIG. 1 is a structural schematic diagram of a cooling system employable in a data center according to an embodiment of the present disclosure;

FIG. 2 is a structural schematic diagram of collaboration between a main first condenser or a standby first condenser and a first evaporator;

FIG. 3 is a structural schematic diagram of collaboration between a control apparatus and a temperature sensor, a barometric sensor and a valve;

FIG. 4 is a structural schematic diagram of an all-condition cooling tower based on a closed cooling tower;

FIG. 5 is a structural schematic diagram of an all-condition cooling tower based on an opening cooling tower; and

FIG. 6 is a schematic diagram of a modular deployment solution of a cooling system employable in a data center provided by the present disclosure;

wherein: 1, a first evaporator; 2, a first condenser, 21, a main first condenser, 22, a standby first condenser; 3, an all-condition cooling tower, 31, a second condenser, 32, a second compressor, 33, a heat radiating coil, 34, a second evaporator, 35, a third compressor, 36, a third condenser, 37, a third evaporator, 38, a spraying component; 41, a main water outlet pipe, 42, a main water return pipe, 43, a first branch pipe, 44, a second branch pipe, 5, a quick coupling; 6, a control apparatus; 7, a temperature sensor; 8, a barometric sensor; and 9, a valve.

### DETAILED DESCRIPTION OF EMBODIMENTS

The present disclosure will be further described in detail below with reference to accompanying drawings and embodiments. It should be understood that, the specific embodiments described herein are merely intended to explain related invention rather than limit the invention. In addition, it should also be noted that, for the convenience of description, only parts related to the invention are shown in the accompanying drawings. It will also be understood by those skilled in the art that, although the terms “first,” “second,” “third” may be used herein to describe various devices such as condensers, evaporators, compressors, these condensers, evaporators, compressors should not be limited by these terms. These terms are only used to distinguish a condenser, evaporator, compressor from other condensers, evaporators, compressors.

The present disclosure will be described in detail below with reference to the accompanying drawings and embodiments.

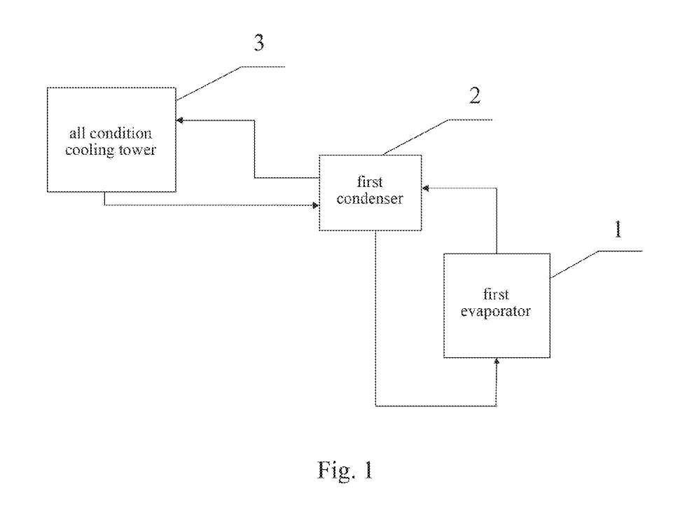

FIG. 1 is a structural schematic diagram of a cooling system employable in a data center according to an embodiment of the present disclosure.

The cooling system employable in data centers of the present embodiment comprises: a first refrigeration medium, a first evaporator 1, a first condenser 2 and an all-condition cooling tower 3.

In the present embodiment, the above-mentioned first evaporator 1 is installed in a to-be-cooled space.

Here, the above-mentioned first evaporator 1 may be various types of commercially available evaporators, and details are not repeated herein. The to-be-cooled space may be a computer room in the data center or a to-be-cooled cabinet within the data center.

In the present embodiment, the above-mentioned first evaporator 1 is connected to the above-mentioned first condenser.

Here, the first condenser 2 may be disposed inside the to-be-cooled space, or may be disposed outside the to-be-cooled space. The first evaporator 1 and the first condenser 2 may be connected through pipes.

In the present embodiment, the installation position of the above-mentioned first condenser 1 is higher than the installation position of the above-mentioned first evaporator 2. The above-mentioned first refrigeration medium in the above-mentioned first evaporator 1 absorbs heat from the above-mentioned to-be-cooled space and is vaporized into the first refrigeration medium in a gaseous state, the above-mentioned first refrigeration medium in the gaseous state rises to the above-mentioned first condenser 2 and is cooled by the above-mentioned first condenser 2 to be liquefied into the first refrigeration medium in a liquid state, the above-mentioned first refrigeration medium in the liquid state returns to the above-mentioned first evaporator 1.

It should be noted that, the installation position of the above-mentioned first condenser 2 is higher than the installation position of the above-mentioned first evaporator 1, thus the gravity may be relied on to perform the circulation of the first refrigeration medium between the first condenser 2 and the first evaporator 1, and no power equipment need to be installed to promote the circulation, simplifying the system structure and saving costs.

In the present embodiment, the above-mentioned first condenser 2 is connected to the above-mentioned all-condition cooling tower 3, the above-mentioned all-condition cooling tower 3 is disposed outside the above-mentioned to-be-cooled space, and the above-mentioned all-condition cooling tower 3 is used for providing the above-mentioned first condenser with a cold source cooling the above-mentioned first refrigeration medium in the gaseous state.

Here, the all-condition means that the all-condition cooling tower can supply the first condenser with a cold source regardless of ambient temperatures. The ambient temperature may be a wet-bulb temperature, and the calculation method for the wet-bulb temperature is well known to those skilled in the art, thus details will not be repeated herein. The all-condition cooling tower may be an alteration based on the open cooling tower, and may also be an alteration based on the closed cooling tower.

It should be noted that, the cooling tower in the conventional technology is generally used in situations where the ambient temperature is low. In the case of a higher ambient temperature, cold water units are usually used to provide the cold source to the data center, resulting in a complex structure of the cooling system in the conventional technology.

The cooling system employable in the data center provided by the present embodiment utilizes the phase change of the first refrigeration medium for heat exchange, which improves the cooling efficiency. The cooling water having higher temperature provided by the all-condition cooling towers for the above-mentioned first condenser meets the cooling needs of the data center, which eliminates the installation of the cooling units used in the conventional technology. The cooling system provided by the present embodiment has advantages of a simple structure, convenient installation and maintenance, and low cost.

In some optional implementations of the present embodiment, the first evaporator and the first condenser may be evaporators and condensers disposed utilizing the heat pipe principle. The first evaporator and the first condenser are integrally disposed as a heat pipe system. The first evaporator serves as the vaporization end of the heat pipe system, while the first condenser serves as the condensation end.

It should be noted that, due to the large temperature difference between the first evaporator and the first condenser, the first evaporator and the first condenser utilizing the heat pipe principle conduct the heat rapidly. The internal space of the heat pipe is vacuumed into a negative pressure state, and is filled with an adequate first refrigeration medium, herein a volatile first refrigeration medium of low boiling point may be chosen. One end of the first evaporator is the evaporation end while one end of the first condenser is the condensation end. When the evaporation end is heated, the liquid in the evaporation end evaporates rapidly, under a slight pressure difference the first refrigeration medium in the gaseous state flows to the other end and releases heat at the condensing end and then re-condenses into liquid, then the liquid flows back to the evaporation end along porous material disposed in the connecting pipe by the capillary effect. The circulation keeps cycling and the heat is transferred from one end of the heat pipe to the other end. The heat circulation proceeds fast, thus the heat in the to-be-cooled space may be absorbed quickly, realizing high efficient cooling.

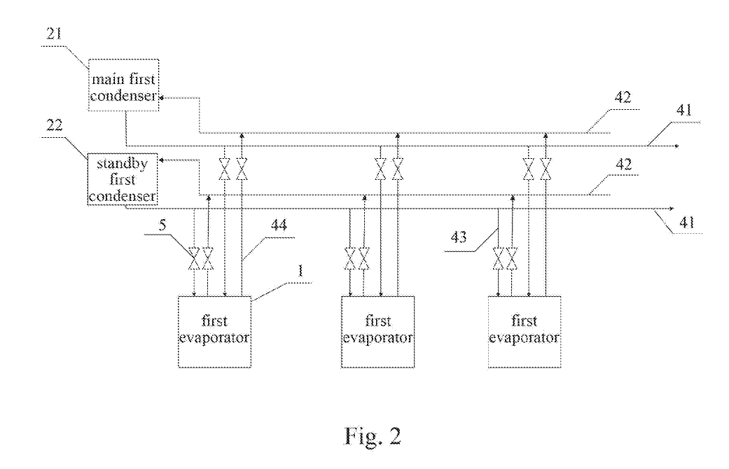

Referring to FIG. 2, in some optional implementations of the present embodiment, the above-mentioned first condenser comprises a main first condenser 21 and a standby first condenser 22, the above-mentioned main first condenser 21 and the above-mentioned standby first condenser 22 are both connected to the above-mentioned first evaporator 1, the above-mentioned main first condenser 21 or the above-mentioned standby first condenser 22 cools the above-mentioned first refrigeration medium in a gaseous state. FIG. 2 is a structural schematic diagram showing the main first condenser, the standby first condenser and the first evaporator work as a group.

It should be noted that, by employing a design of dual first condenser (for example, one main first condenser and one standby first condenser) and dual pipelines, when fault or maintenance occurs to any first condenser and/or the correspondingly connected pipelines, the first evaporators 1 can all be switched through the couplings and connected by pipelines to the other non-fault first condensers. This method can improve the operation and maintenance efficiency of the cooling system.

In some optional implementations of the present embodiment, as shown in FIG. 2, the connecting pipes between the above-mentioned first evaporator and the above-mentioned first condenser may comprise a main pipe and a branch pipe. One of the first condenser may correspond to one of the main water outlet pipe 41 and one of the main water return pipe 42. One of the main water outlet pipe 41 may draw forth a plurality of first branch pipes 43 respectively connected to the first evaporator 1, the first refrigeration medium in the liquid state returns to one of the first evaporators 1 from one of the first condensers 2 through the main water outlet pipe 41 and one of the first branch pipes 43. One of the main water return pipes 42 may draw forth a plurality of second branch pipes 44 respectively connected to one of the first evaporator 1, the first refrigeration medium in the gaseous state rises to the first condenser from one of the first evaporator 1 through one of the second branch pipes 44 and one of the main water return pipes 42.

In some optional implementations of the present embodiment, the above-mentioned first evaporator 1 and the above-mentioned first condenser 2 are connected through a flexible hose, the above-mentioned flexible hose is provided with a quick coupling.

In some optional implementations, the first branch pipe 43 and the second branch pipe may both be using flexible hoses, and the flexible hoses are provided with a quick coupling.

Further, in some optional implementations, the main water outlet pipe 41 and the main water return pipe 42 may also be using flexible hoses.

It should be noted that, the use of the flexible hose and quick coupling may prevent leakage of the first refrigeration medium during the process of changing or connecting the pipelines. Also, when the main first condenser 21 or the standby first condenser 22 fails, the first evaporator is quickly connected to the non-faulty first condenser.

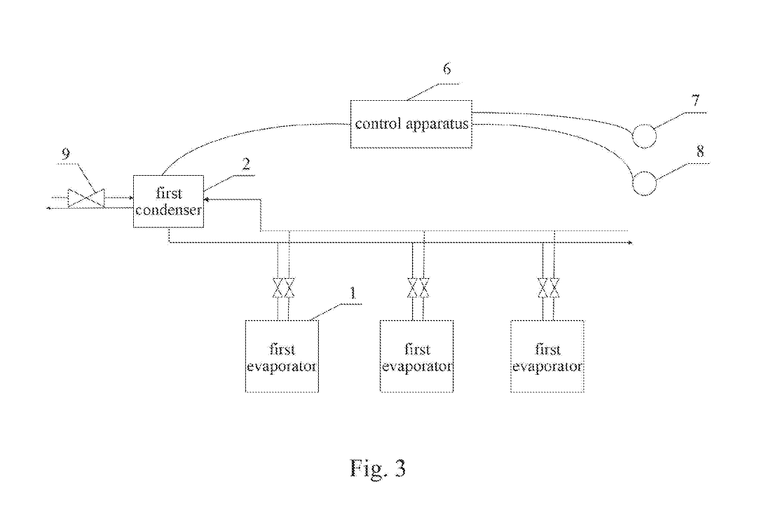

Referring to FIG. 3, in some optional implementations of the present embodiment, the above-mentioned cooling system further comprises a control apparatus 6, a temperature sensor 7, an barometric sensor 8 and a valve 9 in communication with the control apparatus 6. FIG. 3 is a structural schematic diagram showing the control apparatus 6, work with the temperature sensor, barometric sensor and valve as a group.

Here, the above-mentioned temperature sensor 7 and the above-mentioned barometric sensor 8 are both disposed in the to-be-cooled space, and are respectively used for collecting temperature values and barometric pressure values in the to-be-cooled space.

Here, the above-mentioned valve 9 may be disposed on the connecting pipe transporting the cold source from the all-condition cooling tower to the first condenser 2. The above-mentioned control apparatus 6 may be used for determining an opening of the valve 9 according to the temperature values and the pressure values respectively collected by the above-mentioned temperature sensor 7 and the above-mentioned barometric sensor 8.

It should be noted that, the opening of the above-mentioned valve 9 defines the quantity of cold transported to the first condenser 2. In the case of a changing ambient temperature of the to-be-cooled space, changing the quantity of cold delivered to the first condenser 2 may keep the to-be-cooled space with a stable and suitable ambient temperature.

In some optional implementations of the present embodiment, the above-mentioned first refrigeration medium is an organic refrigeration medium.

Here, the above-mentioned organic refrigeration medium may comprise, but not limited to: ethylene glycol and Freon. Common types of organic refrigeration mediums are well-known to those skilled in the art and will not be reeated here.

It should be noted that, the first refrigeration medium is an organic substance, thus even if a leakage of the first refrigeration medium occurs, because organic substance is not conductive, no electrical accident due to the electric conductivity of the refrigeration medium will result. In comparison, in the conventional technology, water is used as the refrigeration medium, which poses a great potential safety hazard. When the first refrigeration medium (water) leaks, an electrical safety accident may happen to the data center due to the electric conductivity of the water.

In some optional implementations of the present embodiment, a to-be-cooled device is disposed in the above-mentioned to-be-cooled space, the above-mentioned first evaporator is an aluminum micro-channel heat exchanger, and the above-mentioned micro-channel heat exchanger is installed on the to-be-cooled device in the form of a backplane.

It should be noted that, installing the micro-channel heat exchanger on the above-mentioned to-be-cooled device as a backplane can improve the cooling efficiency on the to-be-cooled device.

In some optional implementations of the present embodiment, the above-mentioned cooling system further comprises a water pump (not shown) disposed on the connecting pipe between the above-mentioned all-condition cooling tower and the above-mentioned first condenser.

It should be noted that, on the one hand, the above-mentioned disposition of the water pump may speed up a circulation efficiency of the cooling system and improve the refrigeration efficiency; on the other hand, the cooling system of the present disclosure merely provides the all-condition cooling tower as the only equipment providing cold source, eliminating the cooling units and other equipment compared with the existing technology, therefore, the cooling system of the present disclosure may dispose the water pump in this only place, making the system easy to operate and reducing the cost of initial configuration and late maintenance.

Referring to FIG. 4, FIG. 4 is a structural schematic diagram of the all-condition cooling tower based on a closed cooling tower. In some optional implementations of the present embodiment, the above-mentioned all-condition cooling tower includes: a second refrigeration medium, a second condenser 31, a second compressor 32, and a closed cooling tower including a heat radiating coil 33 and a second evaporator 34.

Here, the above-mentioned heat radiating coil 33 is connected to the above-mentioned first condenser, the above-mentioned second refrigeration medium in the above-mentioned first condenser absorbs heat from the first refrigeration medium, and the second refrigeration medium after absorbing heat cools in the above-mentioned heat radiating coil 33, the second refrigeration medium after cooling returns to the above-mentioned first condenser.

Here, the above-mentioned second compressor 32 is connected to the above-mentioned second evaporator 34 and the above-mentioned second condenser 31, the above-mentioned second compressor 32 and the above-mentioned second condenser 31 provide cold source to the second refrigeration medium in the above-mentioned heat radiating coil 33 through the above-mentioned second evaporator 34.

Here, in the case of a lower natural temperature, the second condenser and the second compressor may not be activated, the cold air in the natural environment provides a cold source for the second evaporator, while the second evaporator provides a cold source for the heat radiating coil. In the case of a higher natural ambient temperature, the second condenser and the second compressor are activated to provide a cold source for the second evaporator, while the second evaporator provides a cold source for the heat radiating coil. Due to the higher cooling efficiency of the first condenser and the first evaporator, the temperature of the cooling water transported to the first condenser from the all-condition cooling tower may be relatively high, further, the configured capacity of the second compressor used for high temperature compression cycle in the all-condition cooling tower can be small, usually only less than 50% of the cooling units in a conventional program.

It should be noted that, finishing an all-condition cooling tower by utilizing and improving an existing constructed closed cooling tower, the cost of reconstructing an all-condition cooling tower may be reduced.

In some optional implementations of the present embodiment, the second refrigeration medium is a non-aqueous refrigeration medium.

It should be noted that, the second refrigeration medium is a non-aqueous refrigeration medium, which may reduce water consumption of the cooling system and power consumption of the water pump, saving energy and protecting the environment. Therefore, the approach that the second refrigeration medium is a non-aqueous refrigeration medium is particularly suitable for the data centers constructed in areas of water scarcity.

In some optional implementations of the present embodiment, an installation position of the above-mentioned heat radiating coil is higher than an installation position of the above-mentioned first condenser, the above-mentioned second refrigeration medium absorbs heat from the above-mentioned first refrigeration medium and is vaporized into the second refrigeration medium in a gaseous state, the above-mentioned second refrigeration medium in the gaseous state rises to the above-mentioned heat radiating coil, and the above-mentioned second refrigeration medium in the gaseous state releases heat and is liquefied into the second refrigeration medium in a liquid state in the above-mentioned heat radiating coil, the above-mentioned second refrigeration medium in the liquid state returns to the above-mentioned first condenser.

It should be noted that, a phase-change heat transfer of the second refrigeration medium may improve the refrigeration efficiency. The improvement of the refrigeration efficiency of the second refrigeration medium may reduce working durations of the second condenser and the second compressor and make full use of the natural environment for cooling, saving energy and protecting the environment.

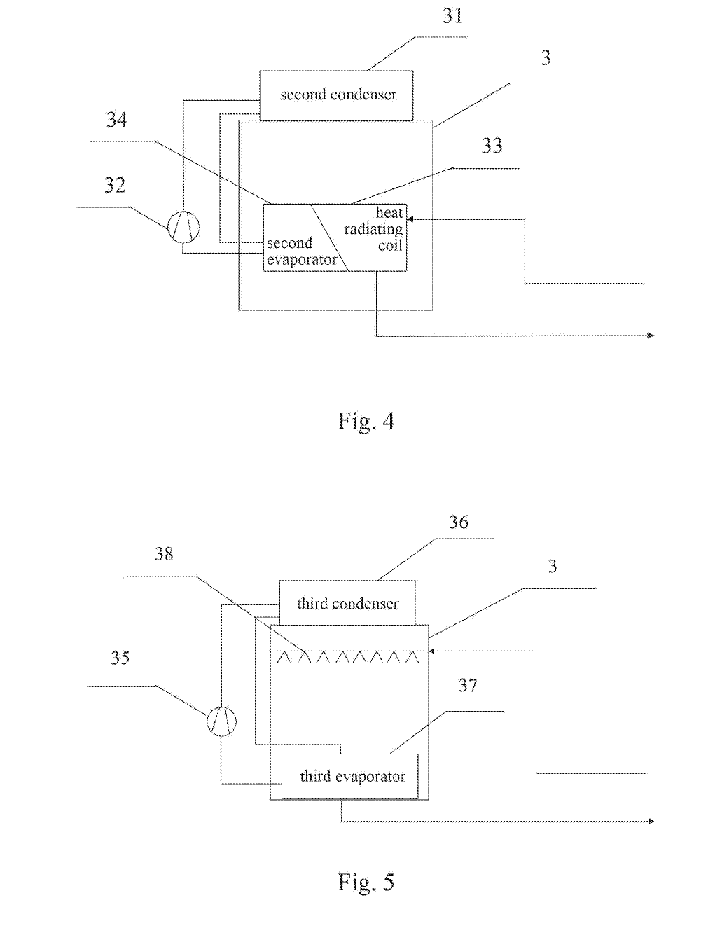

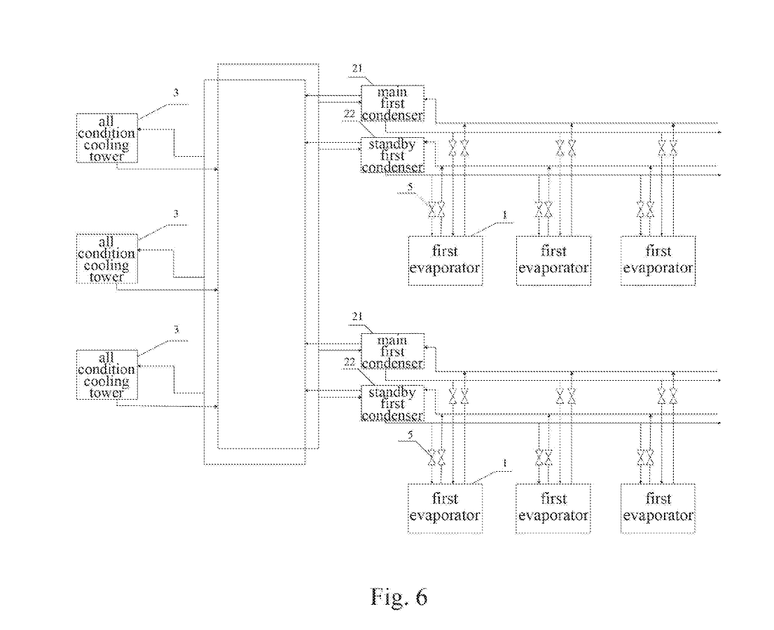

Referring to FIG. 5, FIG. 5 is a structural schematic diagram of the all-condition cooling tower based on an open cooling tower. In some optional implementations of the present embodiment, the all-condition cooling tower comprises: a third refrigeration medium, a third compressor 35, a third condenser 36, a third evaporator 37, and an opening cooling tower comprising a spraying component 38 and a water collector(not shown) locating below the spraying component.

Here, the above-mentioned spraying component 38 is connected to a water outlet of the above-mentioned first condenser, the above-mentioned spraying component is used for spraying the third refrigeration medium received from the water outlet of the above-mentioned first condenser, wherein the sprayed third refrigeration medium exchanges heat with the air for heat releasing, and the third refrigeration medium after releasing the heat falls into the above-mentioned water collector.

Here, the above-mentioned third evaporator is disposed in the above-mentioned water collector, and the above-mentioned third evaporator is used for cooling the third refrigeration medium after releasing the heat. It should be noted that, the third refrigeration medium has the same function as the second refrigeration medium, both providing the cold source for the first refrigeration medium. In the present disclosure, a refrigeration medium cooled by an all-condition cooling tower on the basis of a closed cooling tower is referred to as a second refrigeration medium, and a refrigeration medium cooled by an all-condition cooling tower on the basis of an open cooling tower is referred to as a third refrigeration medium. The present disclosure uses “second” and “third” to distinguish between refrigeration medium of the same function, which is for facilitating the presentation of different all-condition cooling towers.

Here, the above-mentioned water collector is connected to the water inlet of the above-mentioned first condenser, the above-mentioned water collector is used for: receiving a third refrigeration medium after releasing heat, and transporting the third refrigeration medium cooled through the above-mentioned third evaporator to the above-mentioned first condenser.

Here, the above-mentioned third compressor 35 is connected to the above-mentioned third condenser 36 and the above-mentioned third evaporator 37, and the above-mentioned third condenser 36 and the above-mentioned third compressor 35 are used for providing the cold source for the above-mentioned third evaporator 37. In some implementations, the third condenser 36 may be disposed above the open cooling tower without affecting the basic operation of the open cooling tower.

Here, in the case of a lower natural temperature, the third condenser, the third evaporator and the third compressor may not be activated, the cold air in the natural environment provides a cold source for the sprayed second refrigerant medium. In the case of a higher natural ambient temperature, the third condenser, the third evaporator and the third compressor are activated to provide a cold source for the third refrigerant medium in the collector.

It should be noted that, due to the low cost of constructing an open cooling tower, a large number of open cooling towers and cooling units are provided to the cooling system of the existing data center. By removing certain units and reconstructing the open cooling towers as the all-condition cooling towers, it can take full advantages of the equipments in the existing cooling system and reduce the cost of reinvestment in new equipment.

An exemplary illustration of the actual working scenario of the cooling system employable in the data center of the present embodiment is presented here, the various data in this actual working scenario should not be understood as limitations to the present disclosure.

An exemplary data center, the requirement for water output temperature is 25° C., a water output temperature that the cooling system can withstand for a short period is 30° C. Here, the water output temperature may refer to the temperature of the cooling water provided by the all-condition cooling tower for the first condenser. Then:

During winter and its transition seasons, relying on the wet bulb temperatures below 22° C., the all-condition cooling towers may obtain a steady water output temperature of 25° C.

Undermost conditions in summer, relying on the wet bulb temperature of about 23.6° C., the all-condition cooling tower may first obtain a water output of 26.6° C. by naturally cooling down, and finally achieves a water output of 25° C. through a high-temperature compression cycle.

Under rare conditions in summer, when the wet-bulb temperature is 30° C., a water output of 33° C. is preliminary obtained by naturally cooling down, and finally a water output of 30° C. may be obtained through the high-temperature compression cycle of the all-condition cooling tower. It should be noted that, although 30° C. is not the ideal output water temperature, the water output temperature of 30° C. will appear in only a very short period (usually only a few hours) in summer, and the cooling system and the to-be-cooled space can withstand this high temperature in this extremely short period of time. Therefore, the cooling system employable in the data center of the present disclosure may employ the simplified cooling system to meet the cooling requirement of the data center.

It should be noted that, when deploying the structure of the cooling system employable in the data center provided by the present disclosure, a modular deployment solution may be adopted. As shown in FIG. 6, FIG. 6 is a schematic diagram of a modular deployment solution of a cooling system employable in a data center provided by the present disclosure. When constructing the data center building, the main pipeline system was built in one step. The outdoor all-condition cooling tower, as well as the indoor first condenser and first evaporator all may be deployed and expanded on demand.

The above description only provides an explanation of the preferred embodiments of the present disclosure and the technical principles used. It should be appreciated by those skilled in the art that the inventive scope of the present disclosure is not limited to the technical solutions formed by the particular combinations of the above-described technical features. The inventive scope should also cover other technical solutions formed by any combinations of the above-described technical features or equivalent features thereof without departing from the concept of the disclosure. Technical schemes formed by the above-described features being interchanged with, but not limited to, technical features with similar functions disclosed in the present disclosure are examples.

What is claimed is:

1. A cooling system employable in a data center, the cooling system comprising:
a first refrigeration medium;
a first evaporator;
a first condenser; and
an all-condition cooling tower, wherein:
the first evaporator is installed in a to-be-cooled space, the first evaporator is connected to the first condenser, an installation position of the first condenser is higher than an installation position of the first evaporator, the first refrigeration medium in the first evaporator absorbs heat from the to-be-cooled space and is vaporized into the first refrigeration medium in a gaseous state, the first refrigeration medium in the gaseous state rises to the first condenser and is cooled by the first condenser to be liquefied into the first refrigeration medium in a liquid state, the first refrigeration medium in the liquid state returns to the first evaporator; and
the first condenser is connected to the all-condition cooling tower, the all-condition cooling tower is disposed outside the to-be-cooled space, and the all-condition cooling tower is used for providing the first condenser with a cold source cooling the first refrigeration medium in the gaseous state.

2. The cooling system according to claim 1, wherein the first condenser comprises a main first condenser and a standby first condenser, the main first condenser and the standby first condenser are both connected to the first evaporator, and the main first condenser or the standby first condenser cools the gaseous first refrigeration medium.

3. The cooling system according to claim 2, wherein the first evaporator and the first condenser are connected through a flexible hose, and the flexible hose is provided with a quick coupling.

4. The cooling system according to claim 3, wherein the cooling system further comprises a control apparatus, and a temperature sensor, a barometric sensor and a valve in communication with the control apparatus, wherein:
the temperature sensor and the barometric sensor are both disposed in the to-be-cooled space;
the valve is disposed in a connecting pipe transporting the cold source from the all-condition cooling tower to the first condenser; and
the control apparatus is used for defining an opening of the valve according to a temperature value and a pressure value respectively collected by the temperature sensor and the barometric sensor.

5. The cooling system according to claim 4, wherein the first refrigeration medium is an organic refrigeration medium.

6. The cooling system according to claim 5, wherein a to-be-cooled device is provided by the to-be-cooled space, the first evaporator is an aluminum micro-channel heat exchanger, and the micro-channel heat exchanger is installed on the to-be-cooled device as a backplane.

7. The cooling system according to claim 6, wherein the cooling system further comprises a water pump installed on a connecting pipe between the all-condition cooling tower and the first condenser.

8. The cooling system according to claim 1, wherein the all-condition cooling tower comprises a second refrigeration medium, a second condenser, a second compressor, and a closed cooling tower comprising a heat radiating coil and a second evaporator, wherein:
the heat radiating coil is connected to the first condenser, the second refrigeration medium absorbs heat of the first refrigeration medium in the first condenser, the second refrigeration medium after absorbing heat cools in the heat radiating coil, the cooled second refrigeration medium returns to the first condenser; and
the second compressor is connected to the second evaporator and the second condenser, the second compressor and the second condenser provide the cold source for the second refrigeration medium in the heat radiating coil through the second evaporator.

9. The cooling system according to claim 8, wherein the second refrigeration medium is a non-aqueous refrigeration medium, and an installation position of the heat radiating coil is higher than the installation position of the first condenser, the second refrigeration medium absorbs heat of the first refrigeration medium, and is vaporized into the second refrigeration medium in a gaseous state, the second refrigeration medium in the gaseous state rises to the heat radiating coil, and the second refrigeration medium in the gaseous state releases heat in the heat radiating coil and is liquefied into the second refrigeration medium in a liquid state, the second refrigeration medium in the liquid state returns to the first condenser.

10. The cooling system according to claim 1, wherein the all condition cooling tower comprises a third refrigeration medium, a third compressor, a third condenser, a third evaporator, and an open cooling tower comprising a spraying component and a water collector locating below the spraying component, wherein:
the spraying component is connected to a water outlet of the first condenser, the spraying component is used for spraying the third refrigeration medium received from the water outlet of the first condenser, wherein the sprayed third refrigeration medium exchanges heat with the air for releasing heat, and the third refrigeration medium falls into the water collector after releasing the heat;
the third evaporator is disposed in the water collector, and the third evaporator is used for cooling the third refrigeration medium after releasing the heat;
the water collector is connected to a water inlet of the first condenser, the water collector is used for: receiving an third refrigeration medium after releasing the heat, and transporting the third refrigeration medium cooled through the third evaporator to the first condenser; and
the third compressor is connected to the third condenser and the third evaporator, the third condenser and the third compressor are used for providing the third evaporator with the cold source.
